(19) United States
(12) Patent Application Publication
(10) Pub. No.: US 2010/0283074 A1
(43) Pub. Date: Nov. 11, 2010

(54) LIGHT EMITTING DIODE WITH BONDED SEMICONDUCTOR WAVELENGTH CONVERTER

(76) Inventors: Tommie W. Kelley, Shoreview, MN (US); Michael A. Haase, St. Paul, MN (US); Catherine A. Leatherdale, Woodbury, MN (US); Terry L. Smith, Roseville, MN (US)

Correspondence Address: 3M INNOVATIVE PROPERTIES COMPANY, PO BOX 33427, ST. PAUL, MN, 55133-3427, US

(21) Appl. No.: 12/681,878

(22) PCT Filed: Sep. 9, 2008
(86) PCT No.: PCT/US2008/705710

§ 371 Date: Jul. 26, 2010

Related U.S. Application Data
(60) Provisional application No. 60/978,304, filed on Oct. 8, 2007.

(51) Int. Cl. H01L 33/50; H01L 33/00

(52) U.S. Cl. 257/98; 438/27; 257/99; 438/33; 438/29; 257/E33.056; 257/E33.061; 257/E33.067

(57) ABSTRACT

A light emitting diode (LED) has various LED layers provided on a substrate. A multilayer semiconductor wavelength converter, capable of converting the wavelength of light generated in the LED to light at a longer wavelength, is attached to the upper surface of the LED by a bonding layer. One or more textured surfaces within the LED are used to enhance the efficiency at which light is transported from the LED to the wavelength converter. In some embodiments, one or more surfaces of the wavelength converter is provided with a textured surface to enhance the extraction efficiency of the long wavelength light generated within the converter.

### FIELD OF THE INVENTION

The invention relates to light emitting diodes, and more particularly to a light emitting diode (LED) that includes a wavelength converter for converting the wavelength of light emitted by the LED.

### BACKGROUND

Wavelength converted light emitting diodes (LEDs) are becoming increasingly important for illumination applications where there is a need for light of a color that is not normally generated by an LED, or where a single LED may be used in the production of light having a spectrum normally produced by a number of different LEDs together. One example of such an application is in the back-illumination of displays, such as liquid crystal display (LCD) computer monitors and televisions. In such applications there is a need for substantially white light to illuminate the LCD panel. One approach to generating white light with a single LED is to first generate blue light with the LED and then to convert some or all of the light to a different color. For example, where a blue-emitting LED is used as a source of white light, a portion of the blue light may be converted using a wavelength converter to yellow light. The resulting light, a combination of yellow and blue, appears white to the viewer.

In some approaches, the wavelength converter is a layer of semiconductor material that is placed in close proximity to the LED, so that a large fraction of the light generated within the LED passes into the converter. There remains an issue, however, where it is desired that the wavelength converted be attached to the LED die. Typically, semiconductor materials have a relatively high refractive index while the types of materials, such as adhesives, that would normally be considered for attaching the wavelength converter to the LED die have a relatively low refractive index. Consequently, the reflective losses are high due to the high degree of total internal reflection at the interface between relatively high index semiconductor LED material and the relatively low index adhesive. This leads to inefficient coupling of the light out of the LED and into the wavelength converter.

Another approach is direct wafer bonding of the semiconductor wavelength converter to the semiconductor material of the LED die. This approach would provide excellent optical coupling between these two relatively high-index materials. This technique, however, requires exceedingly smooth and flat surfaces, which increases the cost of the resultant LED device. Furthermore, any difference in coefficient of thermal expansion between the wavelength converter and the LED die could lead to adhesive failure with thermal cycling.

### SUMMARY OF THE INVENTION

One embodiment of the invention is directed to a semiconductor stack capable of being diced into multiple light emitting diodes (LEDs). The stack has a LED wafer comprising a first stack of LED semiconductor layers disposed on an LED substrate. At least part of a first side of the LED wafer facing away from the LED substrate comprises a first textured surface. The stack also has a multilayer semiconductor wavelength converter configured to be effective at converting the wavelength of light generated in the LED layers. A bonding layer attaches the first side of the LED wafer to a first side of the wavelength converter.

Another embodiment of the wavelength converter is directed to a method of making wavelength converted, light emitting diodes. The method includes providing an LED wafer comprising a set of LED semiconductor layers disposed on a substrate. At least part of a first side of the LED wafer has a textured surface. The method also includes providing a multilayer wavelength converter wafer configured to be effective at converting wavelength of light generated within the LED layers, and bonding the converter wafer to the textured surface of the LED wafer to produce an LED/converter wafer using a bonding layer disposed between the textured surface and the converter wafer. Individual converted LED dies are separated from the LED/converter wafer.

Another embodiment of the invention is directed to a wavelength converted LED that includes an LED comprising LED semiconductor layers on an LED substrate. The LED has a first surface on a side of the LED facing away from the LED substrate. A multilayered semiconductor wavelength converter is attached to the first surface of the LED. The wavelength converter has a first side facing away from the LED and a second side facing the LED. At least part of one of the first side and the second side of the wavelength converter comprises a first textured surface.

Another embodiment of the invention is directed to a wavelength converted LED that includes an LED comprising a stack of LED semiconductor layers on an LED substrate. At least part of a first side of the stack of LED semiconductor layers facing the LED substrate comprises a first textured surface. A multilayer semiconductor wavelength converter is attached to a side of the LED facing away from the LED substrate.

Another embodiment of the invention is directed to an LED that includes an LED comprising a stack of LED semiconductor layers on an LED substrate. At least part of a first side of the LED substrate facing away from the stack of LED semiconductor layers comprises a first textured surface. A multilayer semiconductor wavelength converter is attached to a side of the LED facing away from the LED substrate.

Another embodiment of the invention is directed to an LED device that includes an LED comprising a stack of LED semiconductor layers on an LED substrate. At least part of an upper side of the stack of LED semiconductor layers stack facing away from the LED substrate having a textured surface. A multilayer wavelength converter formed of a II-VI semiconductor material is attached to the LED semiconductor layer stack. A light blocking feature is provided at the edge of LED semiconductor layers to reduce edge-leakage of light generated within the LED semiconductor layers.

Another embodiment of the invention is directed to a wavelength converted LED device that has an LED comprising a stack of LED semiconductor layers on an LED substrate, the LED having a first textured surface. A multilayer semiconductor wavelength converter is attached by a bonding layer to the LED.

Another embodiment of the invention is directed to a wavelength converter device for an LED. The device includes a multilayer semiconductor wavelength converter element and a bonding layer disposed on one side of the wavelength converter element. There is a removable protective layer over the bonding layer.

The above summary of the present invention is not intended to describe each illustrated embodiment or every implementation of the present invention. The following figures and detailed description more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1 schematically illustrates an embodiment of a wavelength-converted light emitting diode (LED) according to principles of the present invention;

FIGS. 2A-2D schematically illustrate process steps in an embodiment of a manufacturing process for a wavelength converted LED, according to principles of the present invention;

FIG. 3 shows the spectrum of the light output from a wavelength converted LED;

FIGS. 4A and 4B schematically illustrate an embodiment of a wavelength-converted light emitting diode (LED) according to principles of the present invention;

FIG. 5 schematically illustrates another embodiment of a wavelength-converted light emitting diode (LED) according to principles of the present invention;

FIG. 6 schematically illustrates another embodiment of a wavelength-converted light emitting diode (LED) according to principles of the present invention;

FIG. 7 schematically illustrates a process step in an embodiment of a manufacturing process for manufacturing a wavelength converted LED, according to principles of the present invention;

FIG. 8 schematically illustrates another embodiment of a wavelength-converted light emitting diode (LED) according to principles of the present invention; and

FIG. 9 schematically illustrates an embodiment of a multilayered semiconductor wavelength converter.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The present invention is applicable to light emitting diodes that use a wavelength converter that converts the wavelength of at least a portion of the light emitted by the LED to a different, typically longer, wavelength. The invention is directed to a practical and manufacturable method of efficiently using semiconductor wavelength converters with blue or UV LEDs, which are usually based on a nitride material such as AlGaInN. More particularly, some embodiments of the invention are directed to bonding a multilayer, semiconductor wavelength converter using an intermediate bonding layer. The use of a bonding layer removes the requirement for ultraflat surfaces, such as are required when directly bonding two semiconductor elements together. Thus, assembly of the device is possible at the wafer level, which greatly reduces manufacturing costs. Furthermore, if the bonding layer is compliant, for example as may be the case with a polymer bonding layer, the possibility of delamination of the converter layer from the LED when thermally cycling the device is reduced. This is because stresses built up due to differences in the coefficient of thermal expansion (CTE) of the LED and the wavelength converter may be result in some deformation of the compliant bonding layer. In contrast, in the case where the LED is directly bonded to the wavelength converter, the thermal stresses are applied at the interface between the LED and the wavelength converter, which may lead to delamination or damage to the wavelength converter.

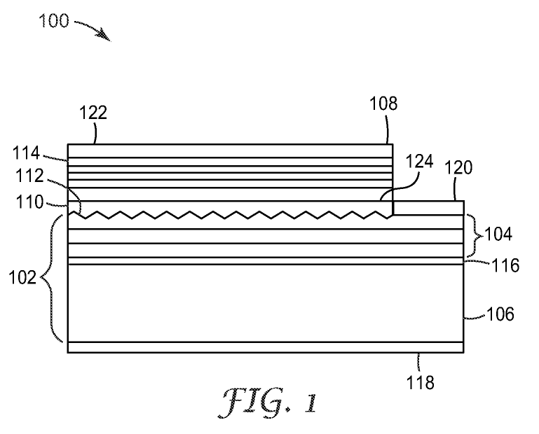

An example of a wavelength-converted LED device 100 according to a first embodiment of the invention is schematically illustrated in FIG. 1. The device 100 includes an LED 102 that has a stack of LED semiconductor layers 104 on an LED substrate 106. The LED semiconductor layers 104 may include several different types of layers including, but not limited to, p- and n-type junction layers, light emitting layers (typically containing quantum wells), buffer layers, and superstrate layers. The LED semiconductor layers 104 are sometimes referred to as epilayers due to the fact that they are typically grown using an epitaxy process. The LED substrate 106 is generally thicker than the LED semiconductor layers, and may be the substrate on which the LED semiconductor layers 104 are grown or may be a substrate to which the semiconductor layers 104 are attached after growth, as will be explained further below. A semiconductor wavelength converter 108 is attached to the upper surface 112 of the LED 102 via a bonding layer 110.

While the invention does not limit the types of LED semiconductor material that may be used and, therefore, the wavelength of light generated within the LED, it is expected that the invention will be found most useful at converting light at the blue or UV portion of the spectrum into longer wavelengths of the visible or infrared spectrum, so the emitted light may appear to be, for example, green, yellow, amber, orange, or red, or, by combining multiple wavelengths, the light may appear to be a mixed color such as cyan, magenta or white. For example, an AlGaInN LED that produces blue light may be used with a wavelength converter that absorbs a portion of the blue light to produce yellow light, with the result that the combination of blue and yellow light appears to be white.

One suitable type of semiconductor wavelength converter 108 is described in U.S. patent application Ser. No. 11/009,217 incorporated herein by reference. A multilayered wavelength converter typically employs multilayered quantum well structures based on II-VI semiconductor materials, for example various metal alloy selenides such as CdMgZnSe. In such multilayered wavelength converters, the quantum well structure 114 is engineered so that the band gap in portions of the structure is selected so that at least some of the pump light emitted by the LED 102 is absorbed. The charge carriers generated by absorption of the pump light move into other portions of the structure having a smaller band gap, the quantum well layers, where the carriers recombine and generate light at the longer wavelength. This description is not intended to limit the types of semiconductor materials or the multilayered structure of the wavelength converter.

The upper and lower surfaces 122 and 124 of the semiconductor wavelength converter 108 may include different types of coatings, such as light filtering layers, reflectors or mirrors, for example as described in U.S. patent application Ser. No. 11/009,217. The coatings on either of the surfaces 122 and 124 may include an anti-reflection coating.

The bonding layer 110 is formed of any suitable material that bonds the wavelength converter 108 to the LED 102 and which is substantially transparent so that most of the light passes from the LED 102 to the wavelength converter 108. For example greater than 90% of the light emitted by the LED 102 may be transmitted through the bonding layer. It is generally desirable to use a bonding layer 110 that has a relatively high thermal conductance: the light conversion in the wavelength converter is not 100% efficient, and the resultant heat can raise the temperature of the converter, which may lead to color shifts and a decrease in the optical conversion efficiency. The thermal conductance can be increased by reducing the thickness of the bonding layer 110 and by selecting a bonding material that has a relatively high thermal conductivity. A further consideration in selection of the bonding material is the potential for mechanical stress created as a result of differential thermal expansion between the LED, the wavelength converter, and the bonding material. Two limits are contemplated. In the case where the coefficient of thermal expansion (CTE) of the bonding material is significantly different than the CTE of the LED 102 and/or wavelength converter 108, it is preferred that the bonding material be compliant, i.e. have a relatively low modulus, so that it can deform and absorb the stress associated with temperature cycling of the LED. The adhesive properties of the bonding layer 110 are sufficient to bond the LED 102 to the wavelength converter 108 throughout the various processing steps used in manufacturing the device, as is explained in greater detail below. In the case where the CTE difference between the bonding material and the LED 102 semiconductor layers is small, higher modulus, stiffer bonding materials may be used.

Useful bonding materials include both curable and non-curable materials. Curable materials can include for example reactive organic monomers or polymers such as acrylates, epoxies, silicon containing resins such as organopolysiloxanes or polysilsesquioxanes, polyimides, perfluorovinyl ethers, or mixtures thereof. Curable bonding materials may be cured or hardened using heat, light, or a combination of both. Thermally-cured material may be preferred for ease of use, but is not necessary for the invention. Non-curable bonding materials may include polymers such as thermoplastics or waxes. Bonding with non-curable materials may be achieved by raising the temperature of the bonding material above its glass transition temperature or its melting temperature, assembling the semiconductor stack and then cooling the semiconductor stack to room temperature (or at least below the glass transition temperature). Bonding materials may include optically clear polymeric materials, such as optically clear polymeric adhesives. Inorganic bonding materials such as sol-gels, sulfur, spin-on glasses and hybrid organic-inorganic materials are also contemplated. Various bonding materials may also be used in combination.

Some exemplary bonding materials may include optically clear polymeric materials, such as optically clear polymeric adhesives, including acrylate-based optical adhesives, such as Norland 83H (supplied by Norland Products, Cranbury N.J.); cyanoacrylates such as Scotch-Weld instant adhesive (supplied by 3M Company, St. Paul, Minn.); benzocyclobutenes such as Cyclotene™ (supplied by Dow Chemical Company, Midland, Mich.); and clear waxes such as CrystalBond (Ted Pella Inc., Redding Calif.).

The bonding material may incorporate inorganic particles to enhance the thermal conductivity, reduce the coefficient of thermal expansion, or increase the average refractive index of the bonding layer. Examples of suitable inorganic particles include metal oxide particles such as Al₂O₃, ZrO₂, TiO₂, V₂O₅, ZnO, SnO₂, and SiO₂. Other suitable inorganic particles may include ceramics or wide bandgap semiconductors such as Si₃N₄, diamond, ZnS, and SiC, or metallic particles. Suitable inorganic particles are typically micron or submicron in size so as to allow formation of a thin bonding layer, and are substantially nonabsorbing over the spectral bandwidth of the emission LED and the emission of the wavelength converter layer. The size and density of the particles may be selected to achieve desired levels of transmission and scattering. The inorganic particles may be surface treated to promote their uniform dispersion in the bonding material. Examples of such surface treatment chemistries include silanes, siloxanes, carboxylic acids, phosphonic acids, zirconates, titanates, and the like.

Generally, adhesives and other suitable materials for use in the bonding layer 110 have a refractive index less than about 1.7, whereas the refractive indices of the semiconductor materials used in the LED and the wavelength converter are well over 2, and may be even higher than 3. Despite such a large difference between the refractive index of the bonding layer 110 and the semiconductor material on either side of the bonding layer 110, it has surprisingly been found that the structure illustrated in FIG. 1 provides excellent coupling of light from the LED 102 to the wavelength converter 108. Thus, the use of a bonding layer is effective at attaching the semiconductor wavelength converter to the LED without having a detrimental effect on extraction efficiency, and so there is no need to use a more costly method of attaching the wavelength converter to the LED, such as using direct wafer bonding.

Coatings may be applied to either the LED 102 or the wavelength converter 108 to improve adhesion to the bonding material and/or to act as antireflective coatings for the light generated in the LED 102. These coatings may include, for example, TiO₂, Al₂O₂, SiO₂, Si₃N₄ and other inorganic or organic materials. The coatings may be single layer or multi-layer coatings. Surface treatment methods may also be performed to improve adhesion, for example, corona treatment, exposure to O₂ plasma and exposure to UV/ozone.

In some embodiments the LED semiconductor layers 104 are attached to the substrate 106 via an optional bonding layer 116, and an electrodes 118 and 120 may be respectively provided on the lower and upper surfaces of the LED 102. This type of structure is commonly used where the LED is based on nitride materials: the LED semiconductor layers 104 may be grown on a substrate, for example sapphire or SiC, and then transferred to another substrate 106, for example a silicon or metal substrate. In other embodiments the LED employs the substrate 106, e.g. sapphire or SiC, on which the semiconductor layers 104 are directly grown.

In certain embodiments the upper surface 112 of the LED 102 is a textured layer that increases the extraction of light from the LED compared to the case where the upper surface 112 is flat. The texture on the upper surface may be in any suitable form that provides portions of the surface that are non-parallel to the semiconductor layers 104. For example, the texture may be in the form of holes, bumps, pits, cones, pyramids, various other shapes and combinations of different shapes, for example as are described in U.S. Pat. No. 6,657,236, incorporated herein by reference. The texture may include random features or non-random periodic features. Feature sizes are generally submicron but may be as large as several microns. Periodicities or coherence lengths may also range from submicron to micron scales. In some cases, the textured surface may comprise a moth-eye surface such as described by Kasugai et al. in Phys. Stat. Sol. Volume 3, page 2165, (2006) and U.S. patent application Ser. No. 11/210,713.

A surface may be textured using various techniques such as etching (including wet chemical etching, dry etching processes such as reactive ion etching or inductively coupled plasma etching, electrochemical etching, or photoetching), photolithography and the like. A textured surface may also be fabricated through the semiconductor growth process, for example by rapid growth rates of a non-lattice matched composition to promote islanding, etc. Alternatively, the growth substrate itself can be textured prior to initiating growth of the LED layers using any of the etching processes described previously. Without a textured surface, light is efficiently extracted from an LED only if its propagation direction within the LED lies inside the angular distribution that permits extraction. This angular distribution is limited, at least in part, by total internal reflection of the light at the surface of the LED's semiconductor layers. Since the refractive index of the LED semiconductor material is relatively high, the angular distribution for extraction becomes relatively narrow. The provision of a textured surface allows for the redistribution of propagation directions for light within the LED, so that a higher fraction of the light may be extracted.

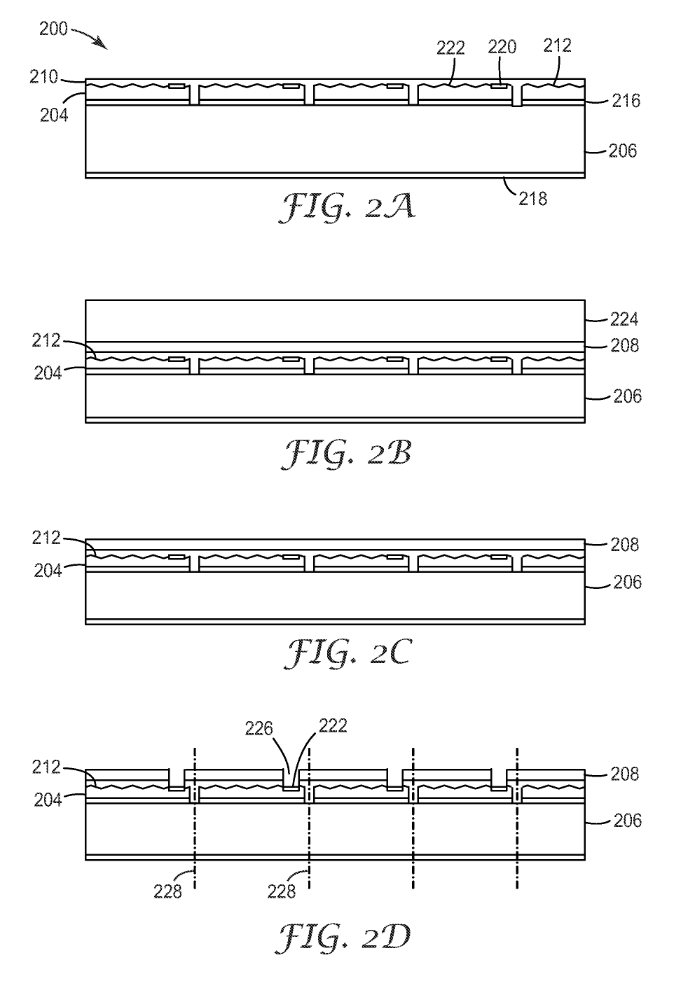

Some exemplary process steps for constructing a wavelength-converted LED device are now described with reference to FIGS. 2A-2D. An LED wafer 200 has LED semiconductor layers 204 over an LED substrate 206, see FIG. 2A. In some embodiments, the LED semiconductor layers 204 are grown directly on the substrate 206, and in other embodiments, the LED semiconductor layers 204 are attached to the substrate 206 via an optional bonding layer 216. The upper surface of the LED layers 204 is a textured surface 212. The wafer 200 is provided with metallized portions 220 that may be used for subsequent wire-bonding. The lower surface of the substrate 206 may be provided with a metallized layer. The wafer 200 may be etched to produce mesas 222. A layer of bonding material 210 is disposed over the wafer 200.

A multilayered semiconductor wavelength converter 208, grown on a converter substrate 224, is attached to the bonding layer 210, as shown in FIG. 2B.

The bonding material 210 may be delivered to the surface of the wafer 200 or to the surface of the wavelength converter 208, or to both, using any suitable method. Such methods include, but are not limited to, spin coating, knife coating, vapor coating, transfer coating, and other such methods such as are known in the art. In some approaches the bonding material may be applied using a syringe applicator. The wavelength converter 208 may be attached to the bonding layer using any suitable method. For example, a measured quantity of bonding material, such as an adhesive, may be applied to one of the wafers 200, 208 sitting on a room temperature hot plate. The wavelength converter 208 or the LED wafer 200 may be then attached to the bonding layer using any suitable method. For example the flat surfaces of the wafers 200, 200 can then be roughly aligned one on top of the other and a weight having a known mass can be added on top of the wafers 200, 208 to encourage the bonding material to flow to the edges of the wafers. The temperature of the hot plate can then be ramped up and maintained at a suitable temperature for curing the bonding material. The hot plate can then be cooled and the weight removed to provide the glue bonded converter-LED wafer assembly. In another approach, a sheet of a selected tacky polymeric material can be applied to a wafer using a transfer liner that has been die cut to wafer shape. The wafer is then mated to another wafer and the bonding material cured, for example on a hot plate as described above. In another approach, a uniform layer of bonding material may be pre-applied to the surface of the wavelength converter wafer and the exposed surface of the bonding material protected with a removable liner until such time as wafers 200 and 208 are ready to be bonded. In the case of curable bonding materials, it may be desirable to partially cure the bonding material so that it has sufficiently high viscosity and/or mechanical stability for handling while still maintaining its adhesive properties.

The converter substrate 224 may then be etched away, to produce the bonded wafer structure shown in FIG. 2C. Vias 226 are then etched through the wavelength converter 208 and the bonding material 210 to expose the metallized portions 220, as shown in FIG. 2D, and the wafer may be cut, for example using a wafer saw, at the dashed lines 228 to produce separate wavelength converted LED devices. Other methods may be used for separating individual devices from a wafer, for example laser scribing and water jet scribing. In addition to etching the vias, it may be useful to etch along the cutting lines prior to using the wafer saw or other separation method to reduce the stress on the wavelength converter layer during the cutting step.

### Example 1

### Metal-Bonded LED with Textured Surface

A wavelength converted LED was produced using a process like that illustrated in FIGS. 2A-2D. The LED wafer 200 was purchased from Epistar Corp., Hsinchu, Taiwan. The wafer 200 had epitaxial AlGaInN LED layers 204 bonded to a silicon substrate 206. As received, the n-type nitride on the upper side of the LED wafer was provided with 1 mm square mesas 222. In addition, the surface was roughened so that some portions had a textured surface 212. Other portions were metallized with gold Au traces to spread the current and to provide pads for wire bonding. The backside of the silicon substrate 206 was metallized with a gold-based layer 218 to provide the p-type contact.

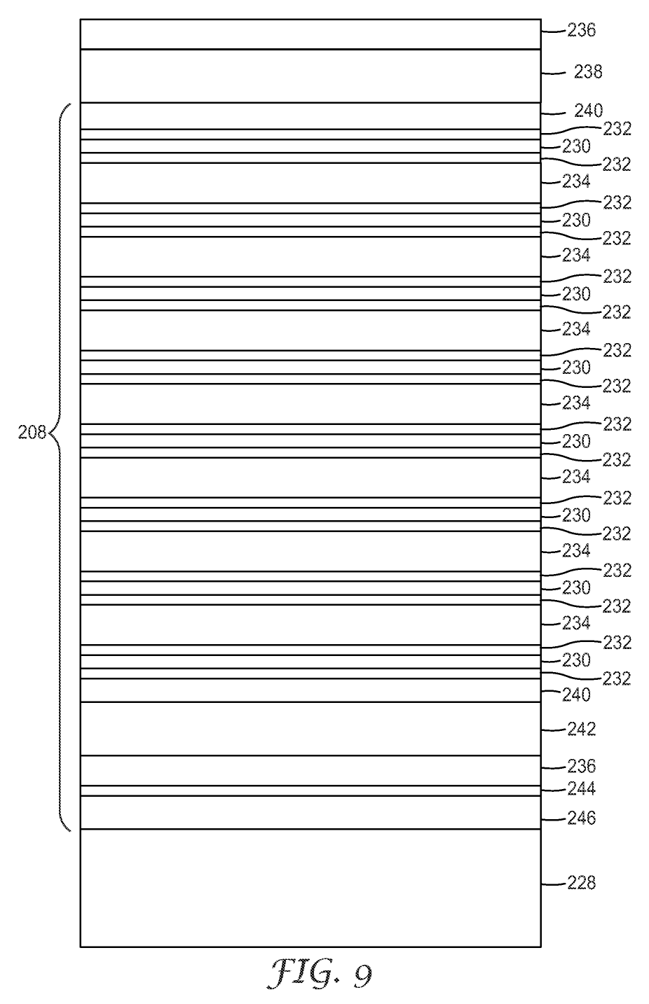

A multilayer, quantum well semiconductor converter 208 was initially prepared on an InP substrate using molecular beam epitaxy (MBE). A GaInAs buffer layer was first grown by MBE on the InP substrate to prepare the surface for II-VI growth. The wafer was then moved through an ultra-high vacuum transfer system to another MBE chamber for growth of the II-VI epitaxial layers for the converter. The details of the as-grown converter 208, complete with substrate 224, are shown in FIG. 9 and summarized in Table I. The table lists the thickness, material composition, band gap and layer description for the different layers in the converter 208. The converter 208 included eight CdZnSe quantum wells 230, each having an energy gap (Eg) of 2.15 eV. Each quantum well 230 was sandwiched between CdMgZnSe absorber layers 232 having an energy gap of 2.48 eV that could absorb the blue light emitted by the LED. The converter 208 also included various window, buffer and grading layers.

TABLE I
Details of Wavelength Converter Structure

| Layer | | Thickness | Band Gap | |
|---|---|---|---|---|
| No. | Material | (\acute{Å}) | (eV) | Description |
| 230 | Cd_{0.48}Zn_{0.52}Se | 31 | 2.15 | Quantum well |
| 232 | Cd_{0.38}Mg_{0.21}Zn_{0.41}Se | 80 | 2.48 | Absorber |
| 234 | Cd_{0.38}Mg_{0.21}Zn_{0.41}Se: Cl | 920 | 2.48 | Absorber |
| 236 | Cd_{0.22}Mg_{0.45}Zn_{0.33}Se | 1000 | 2.93 | Window |
| 238 | Cd_{0.22}Mg_{0.45}Zn_{0.33}Se- | 2500 | 2.93-2.48 | Grading |
| | Cd_{0.38}Mg_{0.21}Zn_{0.41}Se | | | |
| 240 | Cd_{0.38}Mg_{0.21}Zn_{0.41}Se: Cl | 460 | 2.48 | Absorber |
| 242 | Cd_{0.38}Mg_{0.21}Zn_{0.41}Se- | 2500 | 2.48-2.93 | Grading |
| | Cd_{0.22}Mg_{0.45}Zn_{0.33}Se | | | |
| 244 | Cd_{0.39}Zn_{0.61}Se | 44 | 2.24 | |
| 246 | Ga_{0.47}In_{0.53}As | 1900 | 0.77 | Buffer |

The backside of the LED wafer 200 was protected with plating tape (supplied by 3M, St. Paul Minn.) and the epitaxial surface of the converter wafer was attached to the upper surface of the LED wafer using a bonding layer 210 of Norland 83H Optical Adhesive (Norland Products, Inc., Cranbury N.J.). A few drops of the adhesive were placed on the LED surface and the converter wafer was manually pressed onto the adhesive until a bead of adhesive appeared all around the edge of the wafer. The bond was cured on a hot plate at 130° C. for 2 hours. The thickness of the bonding layer 210 was in the range 1-10 μm.

After cooling to room temperature, the back surface of the InP wafer was mechanically lapped and removed with a solution of 3HCl:1H₂O. This etchant stops at the a GaInAs buffer layer in the wavelength converter. The buffer layer was subsequently removed in an agitated solution of 30 ml ammonium hydroxide (30% by weight), 5 ml hydrogen peroxide (30% by weight), 40 g adipic acid, and 200 ml water, leaving only the II-VI semiconductor wavelength converter 208 bonded to the LED wafer 200.

In order to make an electrical connection to the upper side of the nitride LEDs, vias 222 were etched through the wavelength converter 208 and through the bonding layer 210. This was accomplished with conventional contact photolithography using a negative photoresist (NR7-1000PY, Futurrex, Franklin, N.J.). The holes through the photoresist were aligned over the wirebond pads of the LEDs. Since the wavelength converter 208 was transparent to green and red light, alignment for this procedure was straightforward. The wafer was then immersed for about 10 minutes in a stagnant solution of 1 part HCl (30% by weight) mixed with 10 parts H₂O, saturated with Br, to etch the exposed II-VI semiconductor layers of the wavelength converter. The wafer was then placed in a plasma etcher and exposed to an oxygen plasma at a pressure of 200 mTorr and an RF power of 200 W (1.1 W/cm²) for 20 min. The plasma removed both the photoresist and the adhesive that was exposed in the holes that were etched in the wavelength converter. The resultant structure is schematically illustrated in FIG. 2D.

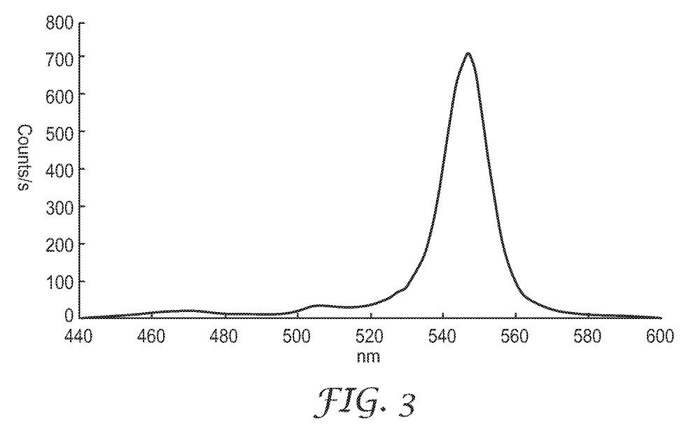

The wafer was then diced with a wafer saw and the individual LED devices were mounted on headers with conductive epoxy and wire bonded. The spectrum of one of the results wavelength converted LED devices is shown in FIG. 3. The dominant emission was generated by the semiconductor converter at a peak wavelength of 547 nm. The blue pump light (467 nm) is almost completely absorbed.

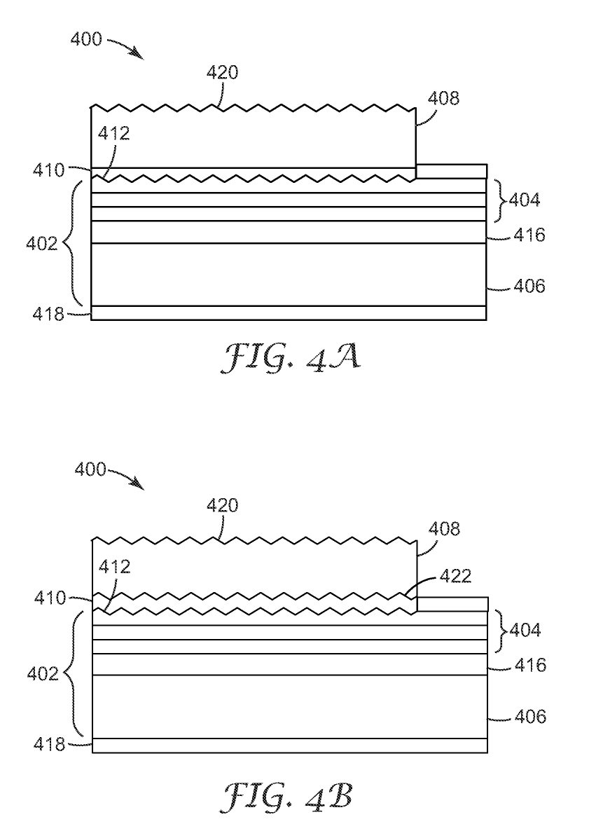

Another embodiment of the invention is schematically illustrated in FIG. 4A. A wavelength-converted LED device 400 includes an LED 402 that has LED semiconductor layers 404 over a substrate 406. In the illustrated embodiment, the LED semiconductor layers 404 are attached to the substrate 406 via a bonding layer 416. A lower electrode layer 418 may be provided on the surface of the substrate 406 facing away from the LED layers 404. A wavelength converter 408 is attached to the LED 402 by a bonding layer 410. At least some of the upper surface 420 of the wavelength converter 408 is provided with surface texture.

In some embodiments, at least part of the lower surface 422 of the wavelength converter, facing the LED 402 may be textured, for example as is schematically illustrated in FIG. 4B. Thus, the wavelength converter 402 may have portions of the upper surface 420 facing away from the LED and/or portions of the lower surface 422 facing the LED textured. The surfaces of the wavelength converter 408 may be textured using techniques like those described above for texturing a surface of the LED. Also, the topography of the textured surface(s) of the wavelength converter may be the same or may be different from texture on the LED. The surface texture of the wavelength converter 408 may be textured using any of the techniques described above.

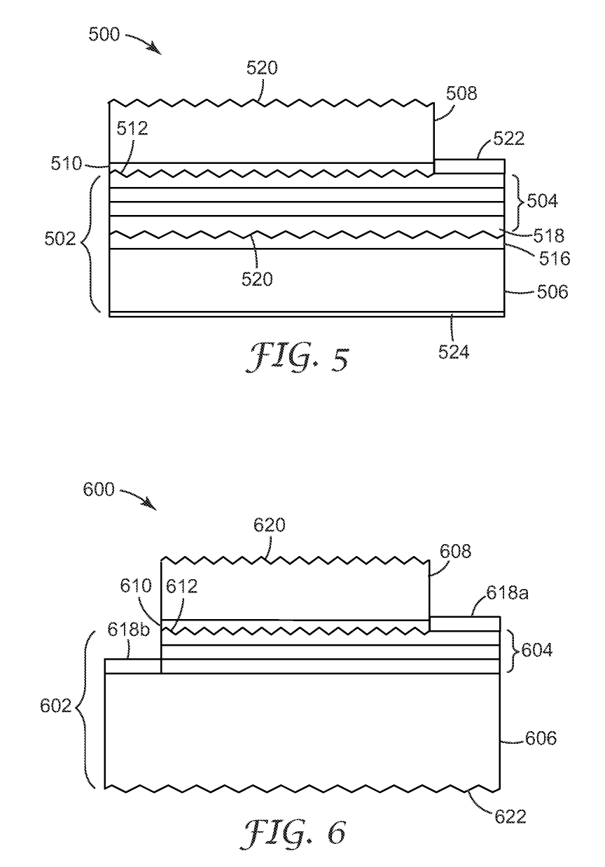

Another embodiment of the invention is schematically illustrated in FIG. 5. A wavelength-converted LED device 500 includes an LED 502 that has LED layers 504 over an LED substrate 506. A wavelength converter 508 is attached to the LED 502 by a bonding layer 510. In this embodiment, the bond 516 between the LED semiconductor layers 504 and the substrate 506 is metallized. Furthermore, the lowest LED layer 518, closest to the LED substrate 506, includes surface texture at the metal-bonded surface 520. In this case, the surface 520 is metallized so as to redirect light within the LED layers 504, with the result that at least some of the light incident at the metallized bond 516 in a direction that lies outside the angular distribution for extraction may be redirected into the extraction angular distribution. The texture of surface 520 may be formed, for example, using any of the techniques discussed above.

The metallized bond 516 may also provide an electrical path between the lower LED layer 518 and the LED substrate 506. In some embodiments, the device 500 may be provided with a textured surface 520 on the output surface of the wavelength converter 508, although this is not a necessary condition.

The semiconductor wavelength converter wafer may be applied to the LED as in Example 1, for example using a thermally curable adhesive material. As in Example 1, only one set of vias is normally required, providing electrical access to the top of the LED 502.

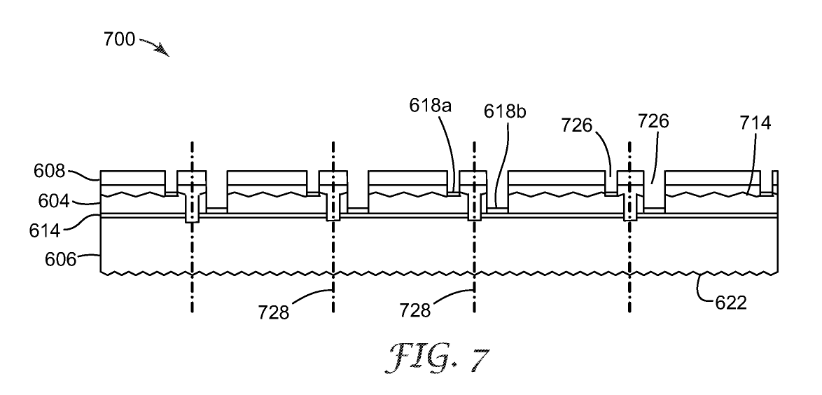

Another embodiment of the invention is now described with reference to FIG. 6. In this embodiment, a wavelength converted LED device 600 includes an LED 602 that has LED layers 604 attached to an LED substrate 606. The LED layers 604 may be grown on the LED substrate 606 or may be attached via a bonding layer (not shown). A wavelength converter 608 is attached to the LED 602 by a bonding layer 610. The wavelength converter 608 may be applied to the LED 602 in a manner similar to that discussed in Example 1, using a bonding material chosen for its optical and mechanical properties.

The LED substrate 606 may be formed of a transparent material, for example, sapphire or silicon carbide. In this embodiment there are several opportunities to provide textured surfaces to improve coupling of the light from the LED 602 into the wavelength converter. For example, the bottom surface 622 of the LED substrate 606 may be textured. The texture may be etched into the substrate 606 prior to growth of the LED semiconductor layers 604.

In the case where the LED substrate 606 is electrically non-conductive, two bond pads 618a, 618b may be provided. The first bond pad 618a is connected to the top of the LED-semiconductor layers 604, and the second bond pad 618b is connected to the bottom of the LED layers 604. The bond pads may be formed of any suitable metal material, for example gold or gold-based alloys.

### Example 2

### Modeled Effect of the Textured Surface Versus a Flat Surface

A wavelength converted LED having different textured surfaces was modeled using TracePro 4.1 optical modeling software. The LED was modeled as a 1 mm×1 mm×0.01 mm block of GaN. The LED was assumed to be embedded in a hemisphere of encapsulant. The underside of the LED, i.e. the lower side of the LED substrate, was assumed to be provided with a silver reflector having a reflectivity of 88%. A bonding layer, having a thickness of 2 μm and having the same refractive index as the encapsulant, separated the emitting surface of the LED and the semiconductor wavelength converter layer. The converter layer was assumed to have a flat surface on both its input and output sides. The parameters of the model are summarized in Table I below.

TABLE I
Parameters in Used in Efficiency Modeling

| | Thickness | Refractive | Absorption/ |
|---|---|---|---|
| Element | (□m) | Index | pass |
| LED | 10 | 2.39 | 3% @ 460 nm |
| Bonding layer | 2 | 1.41 | 0% |
| Wavelength converter | 2 | 2.58 | 93% @ 460 nm |
| layer | | | |
| Encapsulant | 8 mm diameter | 1.41 | 0% |
| | hemisphere | | |

The absorption/pass is the optical absorption for a single transit of the blue light through the optical element, e.g. for a case where the absorption is 3% per pass, the absorption coefficient α=−ln (0.97)/t where t is the layer thickness in mm.

Emission from the LED die was modeled using two embedded uniform grid sources (half angle=90°) centered in the middle of the LED. The amount of light coupled into the semiconductor wavelength converter layer was calculated for cases i) without the presence of any textured surface, ii) with a textured surface only on the upper side of the LED (i.e. like the device 600, but with surface 612 being the only textured surface), and iii) with a textured surface only on the lower, reflecting, side of the LED (i.e. like the device 600, but with surface 622 being the only textured surface). The textured surface was modeled as close packed square pyramids with a 1 μm base and a side slope angle selected for optimum coupling efficiency. Table II below compares the modeling results for the amount of blue light absorbed by the semiconductor wavelength converter layer with and without the textured surface. The coupling efficiency is defined as the fraction of blue light emitted from the LED that is coupled into the wavelength converter layer and absorbed in the converter layer. In case ii) the pyramidical texture had an apex angle of 80°, and in case iii) the apex angle 120°. The modeling software was unable to consider a device having more than one textured surface.

TABLE II
Coupling Efficiency

| | Coupling |
|---|---|
| Condition | efficiency |
| i) Flat LED | 16% |
| ii) Textured LED emitting surface | 47% |
| iii) Textured surface on the lower substrate side | 51% |

As can be seen, the addition of the textured surface to the LED significantly improves the amount of blue light coupled into the wavelength converter, and a coupling efficiency of around 50% is achievable even when the difference in refractive index between the bonding layer and the wavelength converter is greater than 1.

FIG. 7 shows a wafer 700 that may be cut into devices like those shown in FIG. 6, except that only surfaces 714 and 622 are textured. The vias 726 to the wire bond pads 618a, 618b on the LED semiconductor layers 604 may be provided using photolithography and etching steps. A wire bond can be made to the bond pad 618a, 618b at the bottom of each via, providing electrical contact to each die. The wafer 700 may be cut at the lines 728 to produce individual LED devices. Surface texturing may be provided at other surfaces in the wafer, for example at the top and/or bottom surface of the wavelength converter 608 or at a surface between the LED semiconductor layers 604 and the substrate 606.

In the above embodiments, some stray pump light can escape from the edges of the wavelength converted LED during operation. Although this effect is small in the case of some metal-bonded thin-film LEDs, the effect on the observed color of the LED may be undesirable in some applications. Light-blocking features may be included around the edges of the LED mesas to eliminate this stray light. These features can be provided, for example, during the final fabrication steps of the LEDs on the LED wafer, before bonding of the semiconductor converter material. In one embodiment, the light blocking material can be a photoresist (e.g., to absorb blue or UV pump light). Alternatively, a photolithography and deposition step can be performed to fill all or part of the regions between LED mesas structures with a reflecting or absorbing material. In another approach, the light blocking feature may include multiple layers, for example a light blocking feature may include a combination of a layer of an insulating, clear material and a metallic layer. In such a configuration, the metallic layer would reflect the light back into the LED while the insulating material could ensure electrical insulation between the LED layers and the metallic reflective layer.

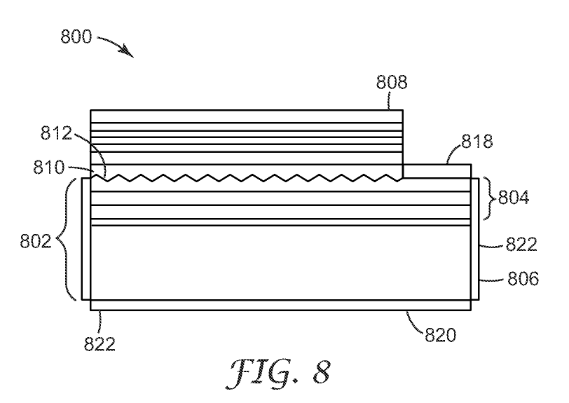

An exemplary embodiment of a wavelength-converted LED device 800 that includes light blocking features is schematically illustrated in FIG. 8. The device 800 includes an LED 802 that has LED semiconductor layers 804 on an LED substrate 806. A wavelength converter 808 is bonded to the LED 802 via a bonding layer 810. In the illustrated embodiment, the upper surface 812 of the LED 802 is a textured surface. Electrodes 818, 820 provide for the application of an electric current to the LED device 800. The light blocking features 822 are provided at the edge of the LED 802 to reduce the amount of light that escapes through the edge of the LED 802. During the wafer stage of manufacture, the light blocking features 824 may be positioned at the cutting locations where individual dies are separated from the wafer.

The present invention should not be considered limited to the particular examples described above, but rather should be understood to cover all aspects of the invention as fairly set out in the attached claims. Various modifications, equivalent processes, as well as numerous structures to which the present invention may be applicable will be readily apparent to those of skill in the art to which the present invention is directed upon review of the present specification. The claims are intended to cover such modifications and devices. For example, while the above description has discussed GaN-based LEDs, the invention is also applicable to LEDs fabricated using other III-V semiconductor materials, and also to LEDs that use II-VI semiconductor materials.

We claim:

1. A semiconductor stack capable of being diced into multiple light emitting diodes (LEDs) comprising:
a light emitting diode (LED) wafer comprising a first stack of LED semiconductor layers disposed on an LED substrate, at least part of the LED wafer comprising a first textured surface;
a multilayer semiconductor wavelength converter configured to be effective at converting the wavelength of light generated in the LED layers; and
a bonding layer attaching the LED wafer to the wavelength converter.

2. A wafer as recited in claim 1, wherein the first textured surface is on a surface of the LED wafer facing away from the LED substrate.

3. A wafer as recited in claim 1, wherein the bonding layer is a polymer layer.

4. A stack as recited in claim 1, wherein at least a part of a first side of the wavelength converter comprises a second textured surface.

5. A stack as recited in claim 4, wherein at least a part of a second side of the wavelength converter comprises a textured surface.

6. A stack as recited in claim 1, wherein the LED substrate comprises a first side facing away from the stack of LED semiconductor layers, at least part of the first side of the LED substrate comprising a third textured surface.

7. A stack as recited in claim 1, further comprising a reflective bonding layer bonding between the LED substrate and the LED semiconductor layers.

8. A stack as recited in claim 7, wherein the reflective bonding layer is a metal layer.

9. A stack as recited in claim 6, further comprising a fourth textured surface between the LED semiconductor layers and the LED substrate.

10. A stack as recited in claim 1, wherein the semiconductor wavelength converter comprises II-VI semiconductor material.

11. A stack as recited in claim 1, wherein the bonding layer comprises inorganic particles disposed within a bonding material.

12. A method of making wavelength converted, light emitting diodes, comprising:
providing a light emitting diode (LED) wafer comprising a set of LED semiconductor layers disposed on a substrate, the LED wafer having a textured surface;
providing a multilayer semiconductor wavelength converter wafer configured to be effective at converting wavelength of light generated within the LED layers;
bonding the converter wafer to the LED wafer to produce an LED/converter wafer using a bonding layer disposed between the LED wafer and the converter wafer; and
separating individual converted LED dies from the LED/converter wafer.

13. A method as recited in claim 12, wherein bonding the converter wafer to the LED wafer comprises bonding the LED wafer to the textured surface of the LED wafer.

14. A method as recited in claim 12, wherein bonding the converter wafer to the textured surface comprises bonding the converter wafer to the textured surface using a polymer material.

15. A method as recited in claim 12, further comprising etching through the converter wafer to expose electrical connection areas of the first side of the LED wafer.

16. A method as recited in claim 12, wherein separating individual converted LED dies comprises dicing the LED/converter wafer using a saw.

17. A method as recited in claim 12, further comprising removing a converter substrate from the converter wafer after bonding the converter wafer to the textured surface.

18. A method as recited in claim 12, wherein bonding the converter wafer to the textured surface comprises bonding a first side of the converter wafer to the textured surface and further comprising texturing a first side of the converter wafer.

19. A method as recited in claim 18, further comprising texturing a second side of the converter wafer.

20. A method as recited in claim 12, further comprising bonding the LED semiconductor layers to the LED substrate using a reflective bonding layer.

21. A method as recited in claim 12, wherein the LED substrate is transparent and further comprising providing a textured surface on a side of the LED substrate facing away from the wavelength converter wafer.

22. A method as recited in claim 20, further comprising providing a textured surface on a side of the LED semiconductor layers facing the second LED substrate.

23. A method as recited in claim 12, further comprising providing light blocking features in the LED/converter wafer and wherein separating the individual LED dies comprises separating the LED/converter wafer at the light blocking features.

24. A method as recited in claim 12, wherein providing the wavelength converter wafer comprises providing a multilayer wavelength converter wafer comprising II-VI semiconductor material.

25. A wavelength converted light emitting diode (LED), comprising:
an LED comprising LED semiconductor layers on an LED substrate, the LED comprising a first surface on a side of the LED facing away from the LED substrate; and
a multilayered semiconductor wavelength converter attached to the first surface of the LED by a bonding layer, the wavelength converter having a first side facing away from the LED and a second side facing the LED, at least part of one of the first side and the second side of the wavelength converter comprising a first textured surface.

26. A device as recited in claim 25, wherein at least a part of the other of the first side and the second side of the wavelength converter comprises a second textured surface.

27. A device as recited in claim 25, wherein at least a part of the first surface of the LED comprises a third textured surface, the wavelength converter being attached to the third textured surface.

28. A device as recited in claim 25, wherein the LED substrate comprises a first side facing away from the wavelength converter, at least part of the first side of the LED substrate comprising a fourth textured surface.

29. A device as recited in claim 25, further comprising a reflective bonding layer attaching the LED substrate to the LED semiconductor layers.

30. A device as recited in claim 25, wherein the LED semiconductor layers have a first side facing the LED substrate, at least part of the first side of the LED semiconductor layers comprising a fifth textured surface.

31. A device as recited in claim 25, further comprising at least one light blocking feature provided at an edge of the LED semiconductor layers to reduce leakage of light generated within the LED semiconductor layers.

32. A device as recited in claim 25, wherein the wavelength converter stack comprises II-VI semiconductor material.

33. A device as recited in claim 25, further comprising a bonding layer disposed between the LED and the wavelength converter.

34. A device as recited in claim 33, wherein the bonding layer comprises inorganic particles disposed within a bonding material.

35. A wavelength converted light emitting diode (LED), comprising:
an LED comprising a stack of LED semiconductor layers on an LED substrate, at least part of a first side of the stack of LED semiconductor layers facing the LED substrate comprising a first textured surface; and
a multilayer semiconductor wavelength converter attached by a bonding layer to a side of the LED facing away from the LED substrate.

36. A device as recited in claim 35, wherein at least a part of a second side of the LED facing away from the LED substrate comprises a second textured surface, the second textured surface being attached to the wavelength converter.

37. A device as recited in claim 35, wherein the wavelength converter comprises a first facing away from the LED and a second side facing the LED, at least part of one of the first and second sides of the wavelength converter comprising a third textured surface.

38. A device as recited in claim 37, wherein at least part of the other of the first and second sides of the wavelength converter comprises a fourth textured surface.

39. A device as recited in claim 35, further comprising at least one light blocking feature provided at an edge of the LED semiconductor layers to reduce leakage of light generated within the LED semiconductor layers.

40. A device as recited in claim 35, wherein the bonding layer comprises a polymer bonding layer.

41. A device as recited in claim 40, wherein the bonding layer comprises inorganic particles disposed within a bonding material.

42. A device as recited in claim 35, wherein the wavelength converter comprises II-VI semiconductor material.

43. A wavelength converted light emitting diode (LED) device, comprising:
an LED comprising a stack of LED semiconductor layers on an LED substrate, at least part of a first side of the LED substrate facing away from the stack of LED semiconductor layers comprising a first textured surface; and
a multilayer semiconductor wavelength converter attached by a bonding layer to a side of the LED facing away from the LED substrate.

44. A device as recited in claim 43, wherein at least a part of a first surface of the stack of LED semiconductor layers facing away from the LED substrate comprises a second textured surface, the second textured surface being bonded to the wavelength converter.

45. A device as recited in claim 43, wherein the wavelength converter comprises a first side facing away from the LED and a second side facing the LED, at least part of one of the first side and the second side of the wavelength converter comprising a third textured surface.

46. A device as recited in claim 45, wherein at least a part of the other of the first side and the second side of the wavelength converter comprises a fourth textured surface.

47. A device as recited in claim 43, wherein the stack of LED semiconductor layers has a first side facing the LED substrate, at least part of the first side of the stack of LED semiconductor layers comprising a fifth textured surface.

48. A device as recited in claim 43, wherein the LED substrate is substantially transparent to light generated within the LED semiconductor layers.

49. A device as recited in claim 43, further comprising at least one light blocking feature provided at an edge of the stack of LED semiconductor layers to reduce leakage of light generated within the LED semiconductor layers.

50. A device as recited in claim 43, further comprising a bonding layer attaching the wavelength converter to the LED.

51. A device as recited in claim 50, wherein the bonding layer comprises a polymer bonding layer.

52. A device as recited in claim 50, wherein the bonding layer comprises inorganic particles disposed within a bonding material.

53. A device as recited in claim 43, wherein the wavelength converter comprises II-VI semiconductor material.

54. A device as recited in claim 43, further comprising a reflective coating on the textured surface of the first side of the LED substrate.

55. A light emitting diode (LED) device, comprising:
an LED comprising a stack of LED semiconductor layers on an LED substrate, at least part of an upper side of the stack of LED semiconductor layers stack facing away from the LED substrate comprising a textured surface;
a multilayer wavelength converter formed of a II-VI semiconductor material and attached to the LED semiconductor layer stack; and
a light blocking feature provided at the edge of LED semiconductor layers to reduce edge-leakage of light generated within the LED semiconductor layers.

56. A device as recited in claim 55, wherein the wavelength converter has a first side facing away from the stack of LED semiconductor layers and a second side facing the stack of LED semiconductor layers, at least part of one of the first side and the second side of the wavelength converter comprising a textured surface.

57. A device as recited in claim 56, wherein at least a part of the other of the first side and the second side of the wavelength converter comprises a textured surface.

58. A device as recited in claim 55, wherein the LED substrate comprises a first side facing away from the wavelength converter, at least part of the first side of the LED substrate comprising a textured surface.

59. A device as recited in claim 55, further comprising a reflective bonding layer attaching the stack of LED semiconductor layers to the LED substrate.

60. A device as recited in claim 55, wherein the LED substrate is substantially transparent to light generated within the LED semiconductor layers, the LED substrate having a first side facing away from the stack of LED semiconductor layers, at least part of the first side of the LED substrate comprising a textured surface.

61. A device as recited in claim 60, wherein the stack of LED semiconductor layers comprises a first side facing the LED substrate, at least part of the first side of the stack of LED semiconductor layers comprising a textured surface.

62. A device as recited in claim 55, further comprising a bonding layer attaching the wavelength converter to the LED.

63. A wavelength converted light emitting diode (LED) device, comprising:
an LED comprising a stack of LED semiconductor layers on an LED substrate, the LED comprising a first textured surface; and
a multilayer semiconductor wavelength converter attached by a bonding layer to the LED.

64. A device as recited in claim 63, wherein the first textured surface is on an output surface of the LED, light passing from the LED via the output surface to the wavelength converter.

65. A device as recited in claim 63, wherein the first textured surface is on the LED substrate.

66. A device as recited in claim 63, wherein the first textured surface is between the LED semiconductor layers and the LED substrate.

67. A device as recited in claim 63, wherein wavelength converter is attached to the first textured surface by the bonding layer.

68. A device as recited in claim 63, wherein the wavelength converter comprises a second textured surface.

69. A wavelength converter device for a light emitting diode (LED), comprising:
a multilayer semiconductor wavelength converter element;
a bonding layer disposed on one side of the wavelength converter element; and
a removable protective layer over the bonding layer.

70. A device as recited in claim 69, wherein the bonding layer is an adhesive bonding layer.

71. A device as recited in claim 69, wherein the bonding layer is a polymeric adhesive bonding layer.

72. A device as recited in claim 69, wherein the wavelength converter element comprises a textured surface.
